(19) United States
(12) Patent Application Publication
(10) Pub. No.: US 2012/0250754 A1
(43) Pub. Date: Oct. 4, 2012

(54) EFFICIENCY-OPTIMIZED CODING FOR HIGH FREQUENCY POWER AMPLIFIERS

(75) Inventors: Wolfgang HEINRICH, Berlin (DE); Erhan ERSOY, Berlin (DE)

(73) Assignee: FORSCHUNGSVERBUND BERLIN E.V., Berlin (DE)

(21) Appl. No.: 13/432,340

(22) Filed: Mar. 28, 2012

(30) Foreign Application Priority Data
Mar. 30, 2011 (DE) 10 2011 006 407.9

(51) Int. Cl. H03K 7/08; H03F 3/217

(52) U.S. Cl. 375/238; 330/207 A

(57) ABSTRACT

The invention introduces a coding unit for a high frequency power amplifier which encodes a useful signal into a binary signal so that a better energy conversion efficiency is achieved—even at an output power below the maximum output power of the high frequency power amplifier. The coding unit has a polar modulation unit, a pulse width modulation unit and a multiplier. Therein, the polar modulation unit has an input connected to an input of the coding unit and is designed to represent an input signal applied to the input of the coding unit as an envelope signal and a binary phasing signal. The pulse width modulation unit is connected to a first output of the polar modulation unit for the envelope signal and is designed to convert the envelope signal into a pulse-width modulated envelope signal and to output it to a first input of the multiplier.

The invention relates to a coding unit for a high frequency power amplifier, a high frequency power amplifier with such a coding unit, a transmitting unit with such a high frequency power amplifier as well as a coding method for operating a high-frequency power amplifier.

### PRIOR ART

In prior art, there are used high frequency power amplifiers which work on the basis of various concepts (class AB, class E, class F, Doherty). Such high frequency power amplifiers may for example be used in antenna output stages of transmitting units. Since high frequency power amplifiers usually make up a large proportion of the power consumption of the system (e.g. in mobile phone base stations), energy conversion efficiency, that is, the ratio between the output power and the total power consumed by the high frequency efficiency amplifier, must be maximized. However, in all types of amplifiers, energy conversion efficiency depends on the instantaneous output power and generally drops with decreasing output power.

The invention was made in view of the realization that a high frequency power amplifier is operated at a maximum output power only for a small proportion of the operating time and that energy conversion efficiency for an operation at a lower output power is lower than at the maximum output power. Since, in spectrum-efficient modulation methods planned in the field of mobile communications, the ratio of maximum to medium output power continues to increase, the question of an increase of energy conversion efficiency even at low powers is currently a very topic issue.

Therefore, the object of the invention is to provide new opportunities for an energetically more favourable operation of a high frequency power amplifier in typical operating cases.

Moreover, the invention is based on the fact that typical transmission signals in the field of wireless communication such as mobile communications or Wireless Local Area Network (WLAN) have a low bandwidth compared to the carrier frequency.

### SUMMARY OF THE INVENTION

A first aspect of the invention therefore introduces a coding unit for a high frequency power amplifier which encodes a useful signal into a binary signal in such way that a better energy conversion efficiency is achieved even at an output power below the maximum output power of the high frequency power amplifier.

The coding unit has a polar modulation unit, a pulse width modulation unit and a multiplier. Therein, the polar modulation unit has an input connected to an input of the coding unit and is designed to represent an input signal applied to the input of the coding unit as an envelope signal and a binary phasing signal. The pulse width modulation unit is connected to a first output of the polar modulation unit for the envelope signal and is designed to convert the envelope signal into a pulse-width modulated envelope signal and to output it to a first input of the multiplier. A second output of the polar modulation unit for the binary phasing signal is connected to a second input of the multiplier. The multiplier is designed to perform a logical AND combination of the binary phasing signal and the pulse-width modulated envelope signal and to output it to an output of the coding unit.

The invention is based on the realization that the best energy conversion efficiency is achieved by using switching amplifiers, that is, amplifiers such as class D and class S amplifiers in which transistors are operated as switches. For this purpose, it is important that the switching amplifier is controlled by a binary signal with the highest possible edge steepness because this ensures that the transition between the binary states, during which a current flows within the transistors and a voltage is simultaneously applied across the drain and source or the collector and emitter of the transistors, is run through as quickly as possible. The invention takes account of that by providing, as a result of the coding, a purely binary control signal for the operation of the switching amplifier through logical combination of binary intermediate signals.

Therein, the invention includes the realization that, in the aforementioned switching amplifiers, the loss power is substantially determined by two effects: firstly, by the amplitude of the switched quantity (according to amplifier topology, voltage or current), and secondly, by the switching operations during the transition between the two stages. Thus, on the one hand the loss power scales with the amplitude of the binary signal, and on the other hand with the number of the switching operations per time unit. However, this means that two optimization conditions exist for the optimization of energy conversion efficiency in the aforementioned sense: on the one hand the binary signal should comprise a highest possible amplitude of the useful signal when the useful signal is at full scale, on the other hand also the number of switching operations per time unit should decrease with a decreasing amplitude of the useful signal in order to keep the deterioration of energy conversion efficiency due to switching losses within limits. Both conditions are not fulfilled in the case of band-pass sigma-delta modulation, which is usually employed for class S amplifiers; there, the ratio of the amplitudes of the useful signal and binary signal can only reach a maximum of approx. 0.8, and the number of switching operations per time unit remains substantially independent of the amplitude of the useful signal.

In contrast, the invention fulfils the conditions by dividing the useful signal into an envelope (amplitude) and a binary phasing signal using a polar modulation unit. Amplitude and phase are also described as polar coordinates, from which derives the name “polar modulation unit”, which is used here.

The phasing signal ideally has only two possible levels (e.g. zero and one) and results directly from the input signal based on the position of the zero or centre passages while the envelope signal represents the envelope and thus a relatively low frequency and usually continuous amplitude signal. In order to convert the envelope signal into a form suitable for controlling a connected high frequency power amplifier, it is converted into a binary representation which happens using the pulse width modulation unit. However, here the term “pulse width modulation” should not only describe the known pulse width modulation, but should also include other modulation methods which are able to convert a continuous-amplitude signal into a binary representation. Here, clocked pulse width modulation methods are preferred due to their simple and robust implementation.

In a preferred embodiment of the invention, the polar modulation unit has a comparator connected between the input of the polar modulation unit and the second output of the polar modulation unit. A comparator has the property of outputting a low signal level when its input value is lower than a pre-determined threshold value, and of outputting a high signal level when its input value is higher than the pre-determined threshold value. In certain implementations with certain signal properties, also separate threshold values may be used (Schmitt trigger property).

The polar modulation unit preferably comprises an envelope detector connected between the input of the polar modulation unit and the second output of the polar modulation unit which may for example include a rectifier and a low-pass filter.

Alternatively, the coding unit may include a polar modulation unit built as a signal processor which is designed to generate the envelope signal and the binary phasing signal from a baseband signal. This means that the envelope signal and the binary phasing signal may also be directly generated or calculated from a signal to be transmitted, that is, a baseband signal, without the need to use for example a separate analog circuit for modulation to a carrier frequency.

A second aspect of the invention introduces a high-frequency power amplifier with a coding unit according to the preceding aspect of the invention, a switching amplifier connected to the output of the coding unit, and a filter unit, preferably a band-pass filter, connected to the output of the switching amplifier. In technical language, one understands by switching amplifiers a variety of types, e.g. those for amplifier classes E, F etc. However, preferred is a type which is controlled by a broadband binary input signal and reproduces the latter at ohmic terminating resistance at the output as such with a greater amplitude (this type is e.g. needed for class S). The filter unit is preferably a band-pass filter, but may also be realized by the transfer function of a following other functional component.

According to the invention, the high frequency power amplifier is controlled by the control signal, which results from the combination of the pulse-width modulated envelope signal and the binary phasing signal in the coding unit and continues to be binary, and amplifies such signal in a broadband manner. The desired power signal is then reconstructed from the output signal by band-pass filtering in the manner known from class S switching amplifiers.

A third aspect of the invention relates to a transmitting unit with a high-frequency power amplifier according to the second aspect of the invention and a transmitting antenna connected to an output of the filter unit of the high-frequency power amplifier.

A fourth aspect of the invention introduces a coding method for operating a high-frequency power amplifier. The coding method comprises at least the following steps:
dividing a useful signal into an envelope signal and a phasing signal;
designing the phasing signal as a binary signal;
pulse-width modulating the envelope signal; and
logical AND combination of the binary phasing signal and the pulse-width modulated envelope signal.

### BRIEF DESCRIPTION OF THE FIGURES

The invention is hereinafter described in more detail with reference to figures of embodiments in which:

FIG. 1 shows a first embodiment of the invention;

FIG. 2 shows a second embodiment of the invention;

FIG. 3 shows a polar modulation unit according to a third embodiment of the invention;

FIG. 4 shows a polar modulation unit according to a fourth embodiment of the invention;

FIGS. 5A through 5F show exemplary curves for explaining the mode of operation of the invention;

FIGS. 6A through 6D show a comparison of the efficiency of a known class S HIGH FREQUENCY power amplifier and the invention; and

FIGS. 7A through 7F show enlarged details of the exemplary curves of FIGS. 5A through 5F.

### DETAILED DESCRIPTION OF THE FIGURES

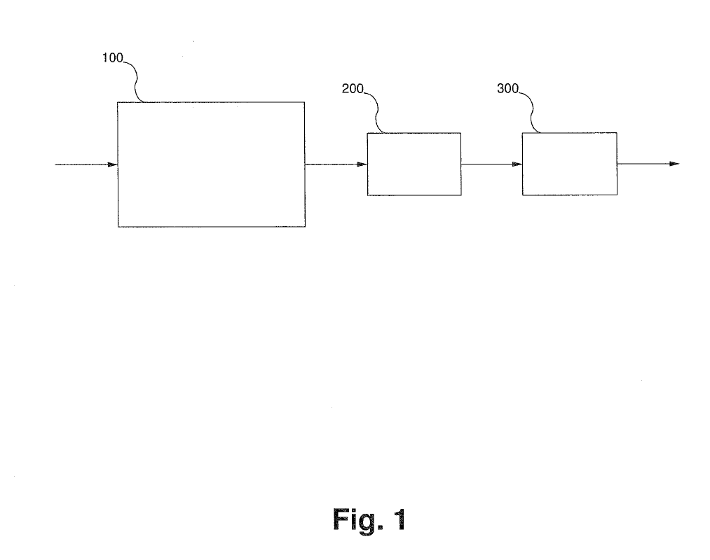

FIG. 1 shows a first embodiment of the invention. According to the invention, a coding unit (100) is provided to convert an input signal into a representation suitable for an efficiency-optimized control of a high-frequency power amplifier built as a switching amplifier. The coding unit 100 has an output which is connected to the input of the connected power amplifier 200. The output of the power amplifier 200 in turn is connected to a filter unit 300 which is preferably built as a band-pass or low-pass filter. The filter unit 300 has the task, known from prior art, to regain the desired transmission signal, which may be a power-amplified copy of the input signal of the coding unit 100, from the output signal of the switching amplifier 200 by filtering.

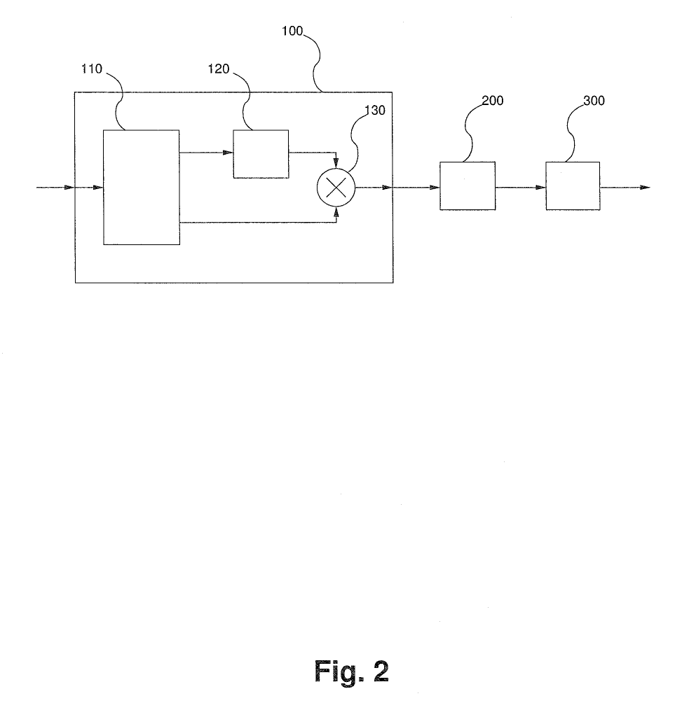

FIG. 2 shows a second embodiment of the invention. As in all figures, same reference numerals refer to same elements, wherein a renewed description of elements already described is omitted.

The coding unit 100 of the second embodiment comprises a polar modulation unit 110, a pulse width modulation unit 120 and a multiplier 130. The polar modulation unit 110 is designed to divide a continuous-amplitude and continuous-time input signal into an envelope (amplitude) and a phasing signal. Idealized, the phasing signal has only two possible output levels symmetrically to a centre voltage and is therefore discrete in amplitude, but continuous in time, which is why it is described as “binary” within the scope of the invention. It transports the phase information of the input signal on the basis of the time position of the edges of the changes between the two possible output levels. The envelope signal, in contrast, describes the amplitude or level of the input signal. With ideal modulator properties, such so-called polar representation includes exactly the full information about the input signal. Therefore, the input signal may be regained by multiplication of the phasing signal and the envelope signal without loss or at least nearly without loss.

According to the invention, the continuous-amplitude and continuous-time envelope signal is given to a pulse width modulation unit 120 which converts it into a discrete-amplitude representation in a known way by classical pulse width modulation.

The multiplier 130 multiplies the two binary input signals applied to its inputs similarly to an AND gate, i.e. the input signal of its phasing signal input appears at its output when its envelope input shows a positive level (logical one), however, a constant level (logical zero or one) when a logical zero is applied to the envelope input. This ensures that the number of the switching operations at the input of the switching amplifier 200 and thus the loss power caused by the switching operations decrease with falling amplitudes of the input signal of the coding unit 100.

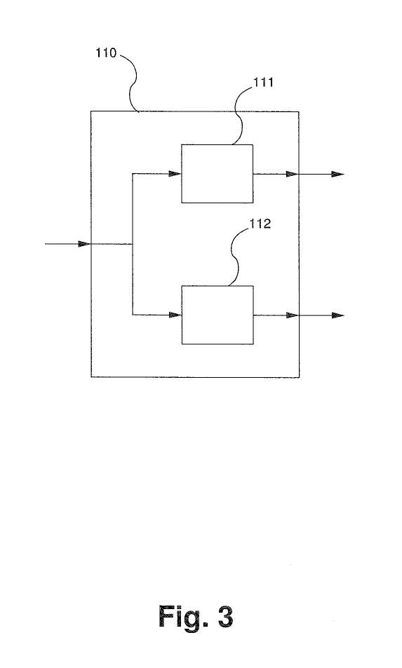

FIG. 3 shows a polar modulation unit according to a third embodiment of the invention. The polar modulation unit 110 includes an envelope detector 111 which is designed to extract the envelope from the input signal and to output it. In addition, the polar modulation unit 110 includes a comparator 112 which is designed to convert the input signal into the binary phasing signal and to output it. If a defined centre potential is not given a threshold voltage of the comparator 112 is preferably adjusted in such way that it corresponds to the mean value of the input signal. An overmodulated amplifier, a flip-flop (latch) or similar known switching elements may also be used as a comparator.

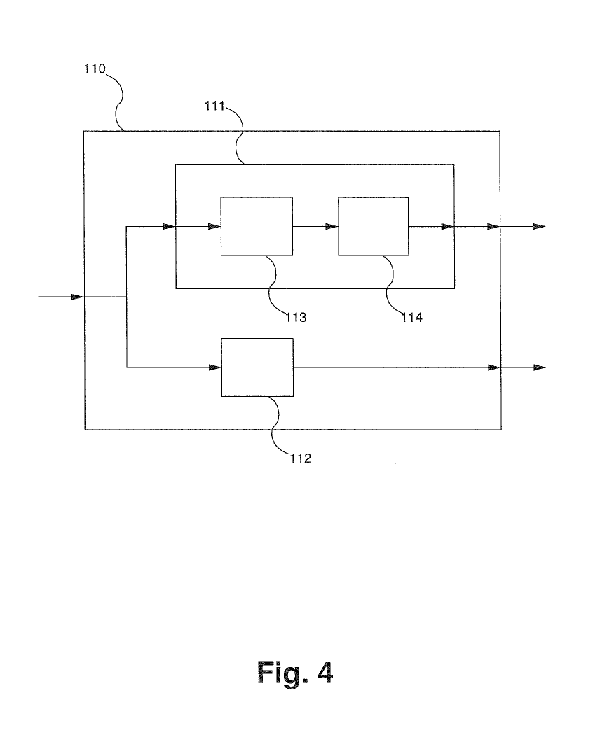

FIG. 4 shows a polar modulation unit according to a fourth embodiment of the invention. In the shown example, the envelope detector 111 is realized by a series connection of a rectifier 113 and a low-pass filter 114. Of course, also other possibilities to build up an envelope detector as known from prior art may be used within the scope of the invention. Thus, it is particularly also possible to gain the binary phasing signal and the envelope signal directly form the raw data to be transferred, that is, for example from a baseband signal. This can be realized using a signal processor, whereby analog modulation methods may not be required. In such embodiments of the invention, the polar modulation unit 110 is realized within the signal processor.

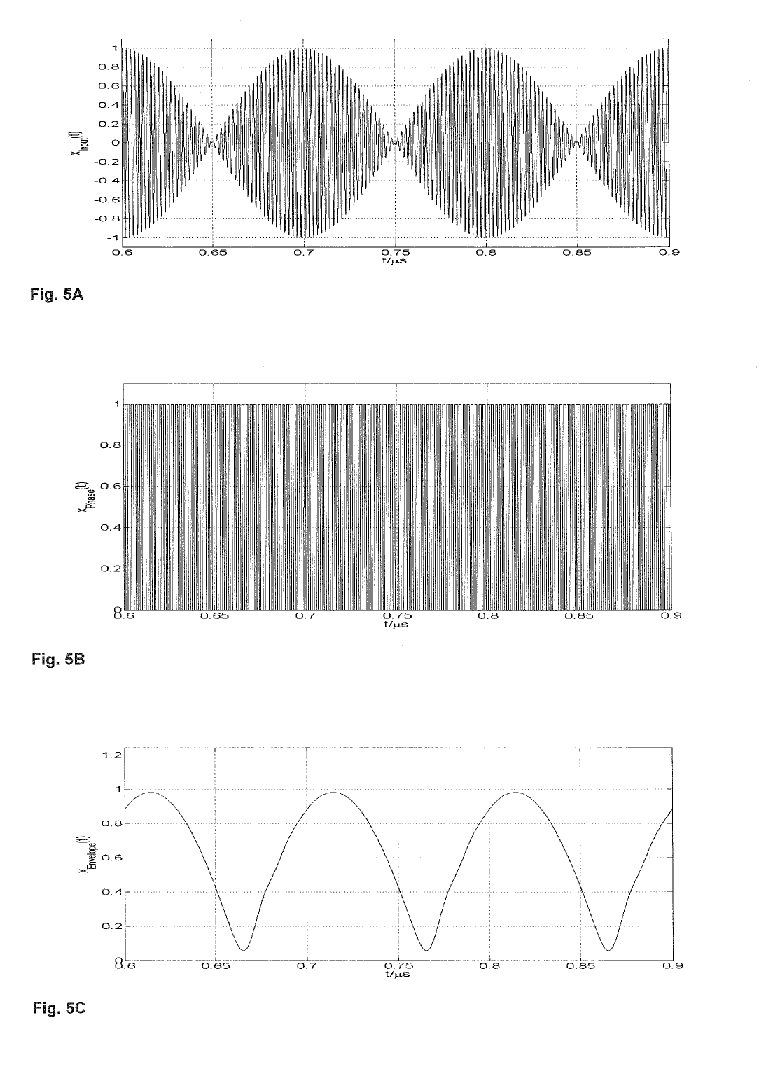

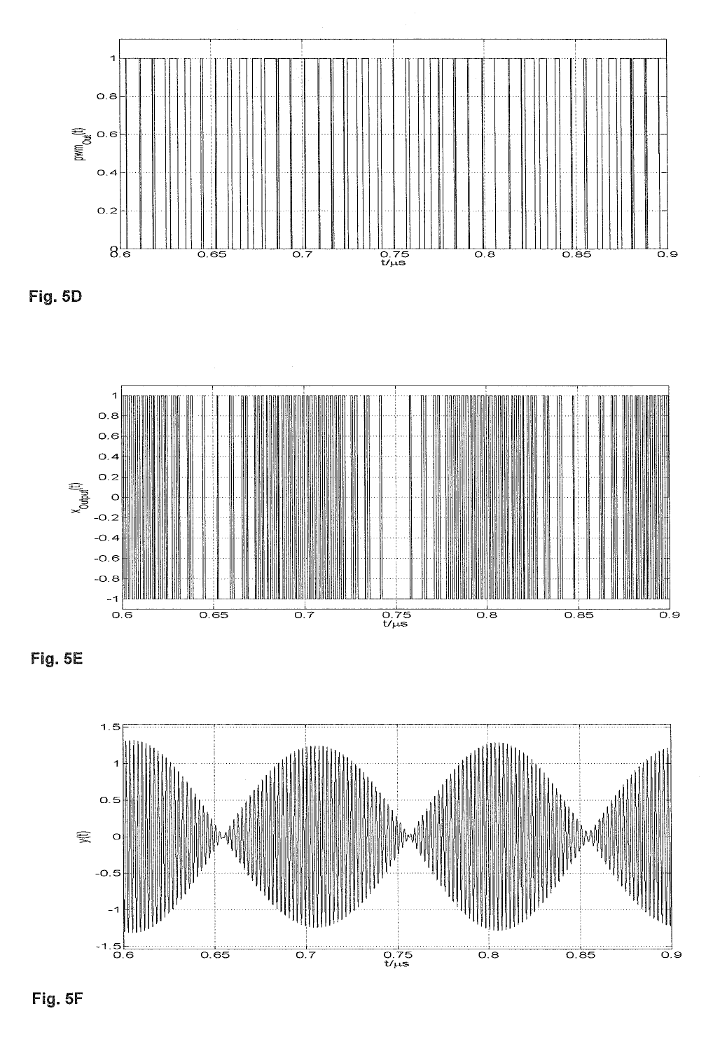

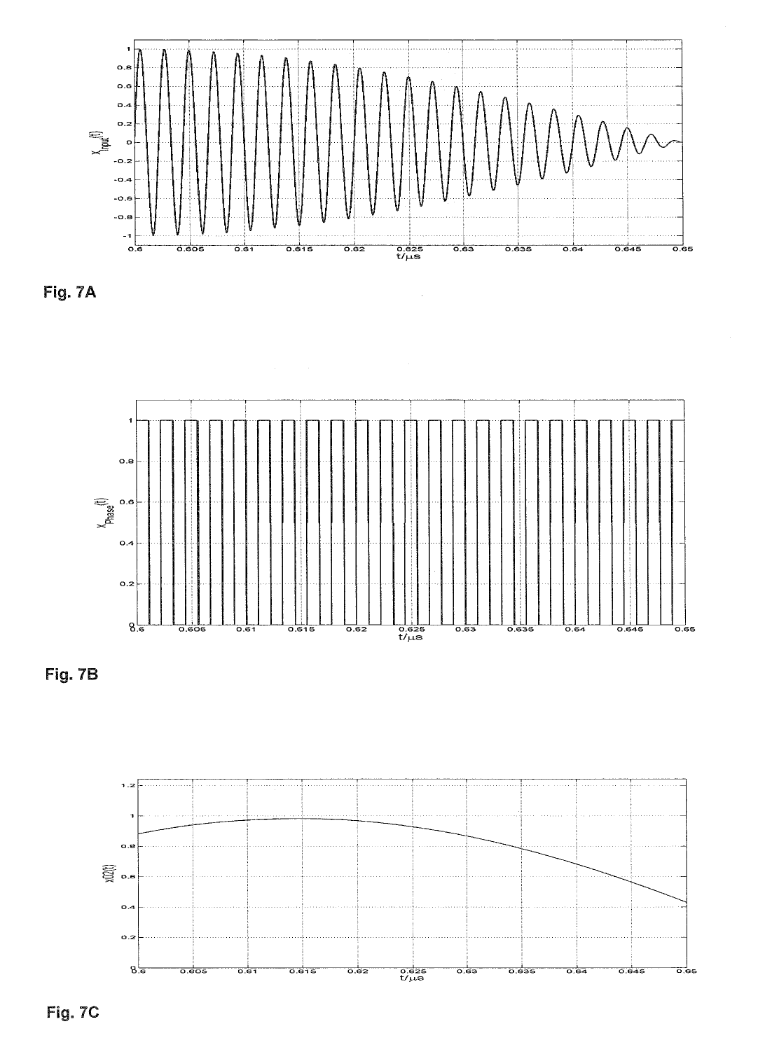

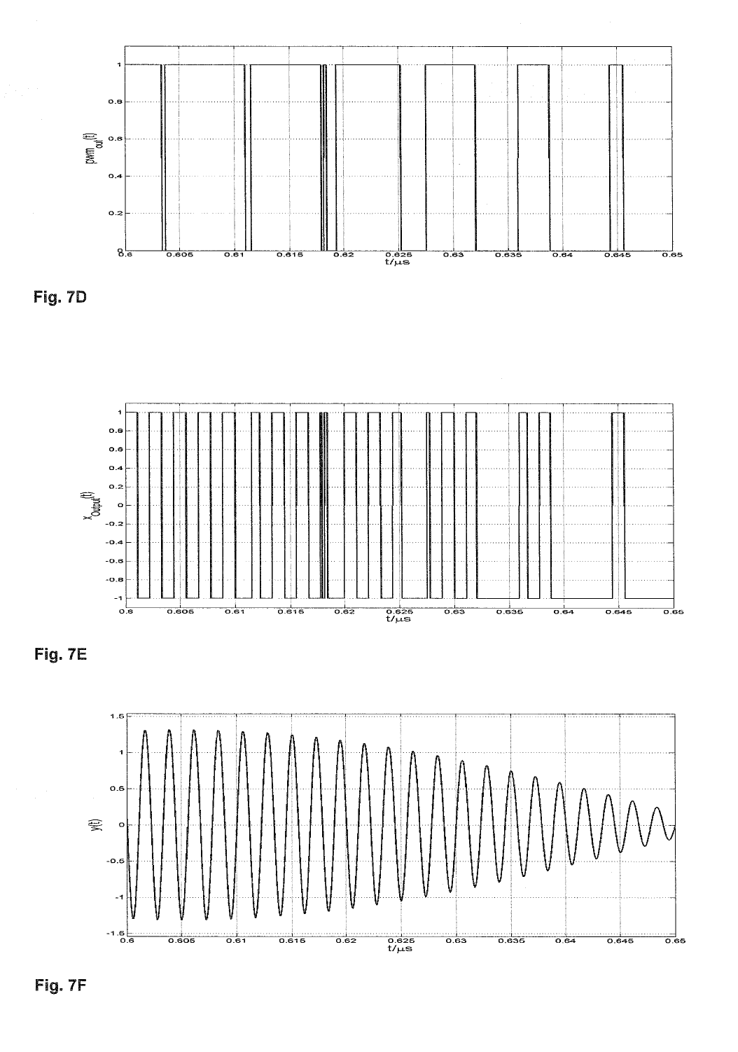

FIGS. 5A through 5F show exemplary curves for explaining the mode of operation of the invention. FIGS. 7A through 7F show enlarged details of the exemplary curves of FIGS. 5A through 5F by way of better visual illustration.

FIG. 5A shows an exemplary input signal which is, for the sake of simplicity, the sum of two sinus signals of similar frequency so that a beat note signal is created. Such input signal is now given to the input of an embodiment of the invention.

The phasing signal generated by the polar modulation unit is illustrated in FIG. 5B. It changes between a low and a high output level with the highest possible edge stiffness, wherein the time position of the edges corresponds to those of the zero passages of the input signal.

FIG. 5C illustrates the envelope of the input signal extracted by the polar modulation unit. A visual examination proves that the input signal illustrated in the first sub-diagram may be regained by multiplication of the envelope signal with the (signed) phasing signal. The envelope signal continues to be continuous in amplitude, which is why it is subjected to a pulse width modulation, the result of which is illustrated in FIG. 5D.

The signals of FIGS. 5B and 5D are now multiplied by each other or ANDed and the result (FIG. 5E) is used for controlling the connected high-frequency power amplifier. At closer examination it has to be noted that the signal of FIG. 5E is also of a continuous-time nature due to the continuous-time phasing signal. FIG. 5F finally illustrates the output signal of the overall arrangement which results from band-pass filtering of the signal of FIG. 5E. The comparison with the signal of FIG. 5A shows that the input signal can be completely reconstructed, wherein it was of course power amplified following the object of the invention.

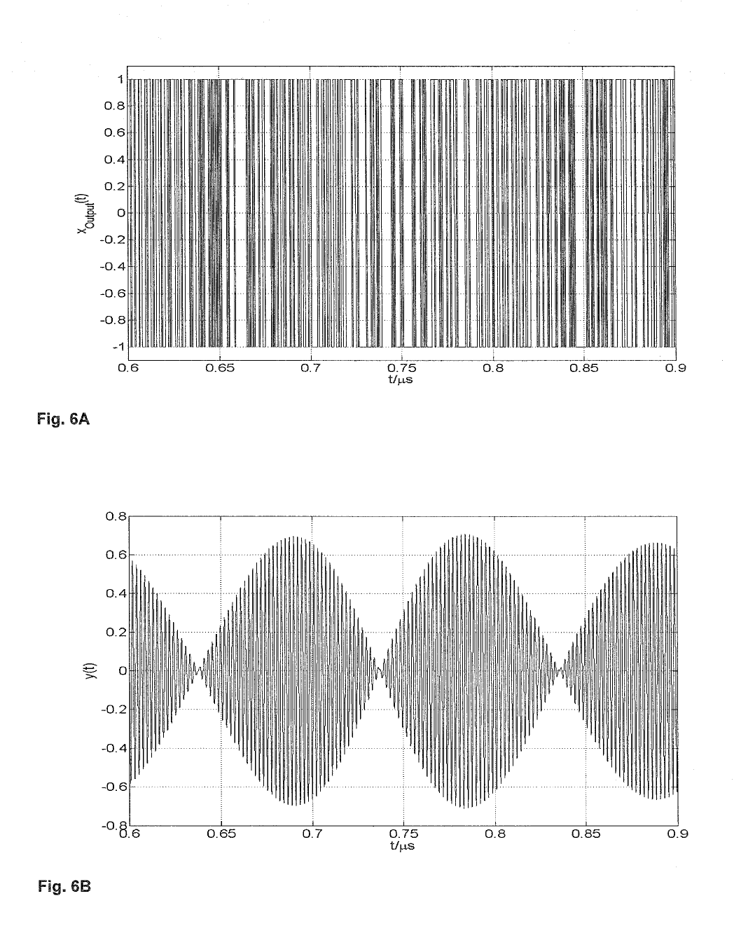

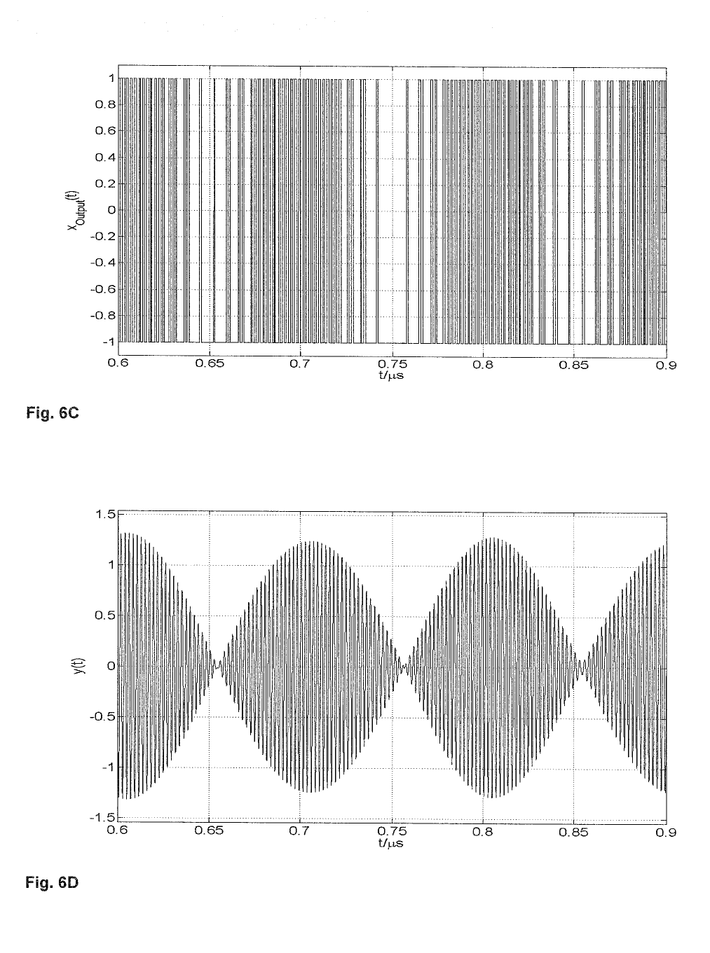

FIGS. 6A through 6D show a comparison of the efficiency of a known class S high frequency power amplifier and the invention. FIGS. 6A and 6B show an input and an output signal of a known class S high frequency amplifier, that is, an input signal modulated by a band-pass delta-sigma modulation (FIG. 6A) and the output signal of the overall arrangement resulting from the filtering of the output signal of the amplifier (FIG. 6B). Therein, for simplifying the illustration, it is assumed that the switching amplifier has the amplification 1. FIGS. 6C and 6D show corresponding signals for an embodiment of the invention, wherein FIG. 6C illustrates the input signal and FIG. 6D illustrates the output signal. Already the comparison of the input signals of the amplifiers of the two examples in FIGS. 6A and 6C discloses that, when using the coding unit of the invention, the switching activity of the amplifier follows clearly more the level of the resulting output signal than in the solution according to prior art, that is, phases of lower level in the desired output signal coincide with phases of lower switching activity. As switching operations involve additional losses, this means that, in contrary to conventional modulation types such as band-pass sigma-delta modulation with fourfold oversampling or usual pulse width modulation, the number of switching operations decreases with falling power of the encoded signal. As the loss power also decreases, this provides advantages with regard to energy conversion efficiency at back-off. The comparison of the output signals of the overall arrangement furthermore proves the advantages of the invention by the fact that, in the case of the invention, the amplitude of the output signal is by more than 80 percent higher than that of the example from prior art (Despite identical control amplitudes, FIG. 6D shows an amplitude of about 1.3 versus only about 0.7 in the example from prior art in FIG. 6B).

1. A coding unit for a high-frequency power amplifier with a polar modulation unit, a pulse width modulation unit and a multiplier, wherein the polar modulation unit has an input connected to an input of the coding unit and is designed to represent an input signal applied to the input of the coding unit as an envelope signal and a binary phasing signal, wherein the pulse width modulation unit is connected to a first output of the polar modulation unit for the envelope signal and is designed to convert the envelope signal into a pulse-width modulated envelope signal and to output it to a first input of the multiplier, wherein a second output of the polar modulation unit for the binary phasing signal is connected to a second input of the multiplier, and wherein the multiplier is designed to perform a logical AND combination of the binary phasing signal and the pulse-width modulated envelope signal and to output it to an output of the coding unit.

2. The coding unit of claim 1 in which the polar modulation unit has a comparator connected between the input of the polar modulation unit and the second output of the polar modulation unit.

3. The coding unit of claim 1 in which the polar modulation unit comprises an envelope detector connected between the input of the polar modulation unit and the first output of the polar modulation unit.

4. The coding unit of claim 3 in which the envelope detector comprises a rectifier and a low-pass filter.

5. The coding unit of claim 1 in which the polar modulation unit is built as a signal processor and is designed to generate the envelope signal and the binary phasing signal from a baseband signal.

6. A high-frequency power amplifier with a coding unit of claim 1, a switching amplifier connected to an output of the coding unit and a filter unit, preferably a band-pass filter, connected to the output of the switching amplifier.

7. A transmitting unit with a high-frequency power amplifier according to claim 6 and a transmitting antenna connected to an output of the filter unit of the high-frequency power amplifier.

8. A coding method for operating a high-frequency power amplifier with the steps of:
dividing a useful signal into an envelope signal and a phasing signal;
designing the phasing signal as a binary signal;
pulse-width modulating of the envelope signal; and
logical AND combination of the binary phasing signal and the pulse-width modulated envelope signal.
